(19) United States
(12) Patent Application Publication
(10) Pub. No.: US 2021/0005667 A1
(43) Pub. Date: Jan. 7, 2021

(54) System on chip (Soc) based on neural processor or microprocessor

(71) Applicants: Mohammad A. Mazed, Yorba Linda, CA (US); Rex Wiig, Chino, CA (US); Angel Martinez, Anaheim, CA (US)

(72) Inventors: Mohammad A. Mazed, Yorba Linda, CA (US); Rex Wiig, Chino, CA (US); Angel Martinez, Anaheim, CA (US)

(21) Appl. No.: 16/974,033

(22) Filed: Sep. 15, 2020

Related U.S. Application Data
(63) Continuation-in-part of application No. 15/530,191, filed on Dec. 12, 2016, now Pat. No. 10,803,941.
Application No. 15/530,191 is a continuation-in-part of application No. 14/757,373, filed on Dec. 22, 2015, now Pat. No. 9,558,779.
(60) Provisional application No. 62/124,613, filed on Dec. 22, 2014.

(51) Int. Cl. H01L 27/24; H01L 25/065; H01L 25/18; H01L 45/00; H01L 51/00; H01L 51/05; G06N 3/04

(52) U.S. Cl. CPC H01L 27/2481; H01L 25/0652; H01L 25/18; H01L 45/06; H01L 45/1213; H01L 45/144; H01L 2225/06541; H01L 45/147; H01L 27/2409; H01L 51/0048; H01L 51/0558; G06N 3/04; H01L 2225/06513; H01L 45/145

(57) ABSTRACT

System on chips (SoCs) based on a microprocessor or a neural processor (e.g., brain-inspired processor) electrically coupled with electronic memory devices and/or optically coupled with an optical memory device, along with embodiment(s) of a building block (an element) of the microprocessor/neural processor, the electronic memory device and the optical memory device are disclosed. It should be noted that a microprocessor can include a graphical processor. Furthermore, two or more microprocessors/graphical processors/neural processors (or even a network of microprocessors/graphical processors/neural processors) can be coupled with an optical switch to mimic a (biological) cognitive system.

### CROSS REFERENCE OF RELATED APPLICATION

The present application
is a continuation-in-part (CIP) of (a) U.S. Non-Provisional patent application Ser. No. 15/530,191 entitled “SYSTEM ON CHIP (SoC) BASED ON NEURAL PROCESSOR OR MICROPROCESSOR”, filed on Dec. 12, 2016,
wherein (a) is a continuation-in-part (CIP) of (b) U.S. Non-Provisional patent application Ser. No. 14/757,373 entitled SYSTEM ON CHIP (SoC) BASED ON PHASE TRANSITION AND/OR PHASE CHANGE MATERIAL”, filed on Dec. 22, 2015,
wherein (b) claims benefit of priority to (c) U.S. Provisional Patent Application No. 62/124,613 entitled, “VANADIUM OXIDE ELECTRONIC MEMORY DEVICE”, filed on Dec. 22, 2014.

The entire contents of all (i) U.S. Non-Provisional patent applications, (ii) U.S. Provisional patent applications, as listed in the previous paragraph and (ii) the filed (Patent) Application Data Sheet (ADS) are hereby incorporated by reference, as if they are reproduced herein in their entirety.

### FIELD OF THE INVENTION

Technologies to replace today's microprocessor and memory device for greater speed, higher density, higher efficiency and neuron-like capabilities are critically needed in the computing marketplace. The present invention generally relates to various system on chips (SoCs) based on a microprocessor and/or graphical processor/neural processor, electrically coupled with electronic memory devices and/or optically coupled with an optical switch, an optical memory device, along with embodiment(s) of building block (an element) of the microprocessor/neural processor (e.g., brain-inspired processor), electronic memory device and optical memory device.

### SUMMARY OF THE INVENTION

A first system on chip—a microprocessor electrically coupling with electronic memory devices and various embodiments of an electronic memory device are disclosed.

A second system on chip—a microprocessor optically coupling with an optical memory device is disclosed.

A third system on chip—a microprocessor optically coupling with an optical memory device and also electrically coupling with electronic memory devices is disclosed.

A fourth system on chip—a neural processor optically coupling with an optical memory device is disclosed.

A fifth system on chip—a neural processor optically coupling with an optical memory device and also electrically coupling with electronic memory devices is disclosed.

A sixth system on chip-one or more microprocessors optically coupling with an optical switch, an optical memory device and also electrically coupling with electronic memory devices is disclosed.

A seventh system on chip-one or more neural processors optically coupling with an optical switch, an optical memory device and also electrically coupling with electronic memory devices is disclosed.

### BRIEF DESCRIPTION OF THE DRAWINGS

FIG. 1A illustrates an embodiment of a first system on chip, wherein a microprocessor is electrically coupling with electronic memory devices.

FIG. 1B illustrates another embodiment of the first system on chip, wherein the microprocessor is electrically coupling with electronic memory devices.

FIG. 2 illustrates an embodiment of a building block (an element: phase transition (PT) based field effect transistor (FET)) of the microprocessor.

FIG. 3 illustrates another embodiment of a building block (an element: carbon nanotube based (CNT) field effect transistor) of the microprocessor.

FIG. 4 illustrates another embodiment of a building block (an element: hybrid phase transition-carbon nanotube (PT-CNT) based field effect transistor) of the microprocessor.

FIG. 5 illustrates an embodiment of a building block (an element: based on a nanoscaled (wherein, the nanoscaled is defined as less than 1000 nanometers in any dimension) phase transition material) of an electronic memory device.

FIG. 6 illustrates another embodiment of a building block (an element: based on a nanoscaled phase transition material) of the electronic memory device.

FIG. 7 illustrates another embodiment of a building block (an element: based on a nanoscaled phase transition material) of the electronic memory device.

FIG. 8 illustrates another embodiment of a building block (an element: based on a nanoscaled phase change/nanoscaled phase transition material) of the electronic memory device.

FIG. 9 illustrates an embodiment of a second system on chip, wherein a microprocessor is optically coupling with an optical memory device.

FIG. 10 illustrates an embodiment of a third system on chip, wherein a microprocessor is optically coupling with the optical memory device and also electrically coupling with the electronic memory devices.

FIG. 11 illustrates an embodiment of a fourth system on chip, wherein a neural processor is optically coupling with the optical memory device.

FIG. 12 illustrates an embodiment of a fifth system on chip, wherein the neural processor is optically coupling with the optical memory device and also electrically coupling with the electronic memory devices.

FIG. 13 illustrates an embodiment of a building block (an element: based on memristors and microprocessors) of the neural processor. It should be noted that a microprocessor can also include a graphical processor.

FIG. 14 illustrates another embodiment of a building block (an element: based on a metal oxide layer releasing oxygen ions) of the neural processor.

FIG. 15 illustrates an embodiment of a building block (an element: based on a phase change material) of the optical memory device. It should be noted that a phase change material can be also replaced by a phase transition material. Additionally, the phase change material/phase transition material can be nanoscaled.

FIG. 16 illustrates an embodiment, wherein microprocessors/neural processors (or even a network of microprocessors/graphical processors/neural processors) are coupled with an optical switch.

FIG. 17 illustrates an embodiment, wherein microprocessors/neural processors (or even a network of microprocessors/graphical processors/neural processors) are coupled with an optical switch, wherein each microprocessor/neural processor is coupled with an electronic memory.

### DETAIL DESCRIPTION OF THE DRAWINGS

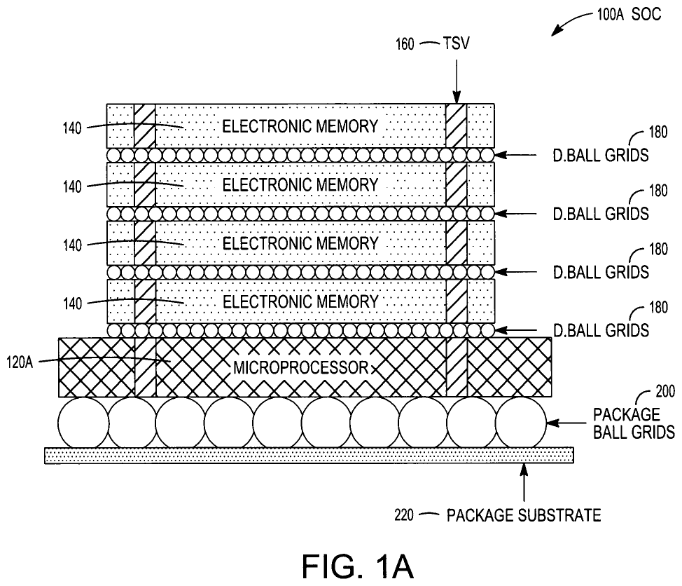

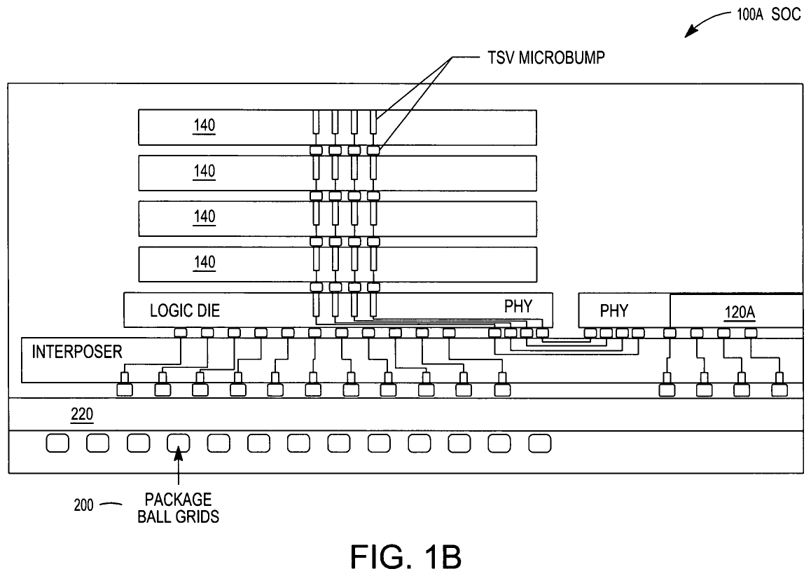

FIG. 1A illustrates an embodiment of 100A—a first system on chip. In FIG. 1A, 120A—a microprocessor is electrically coupled with 140s—the electronic memory devices through 160—a metalized through-semiconductor via hole (TSV) Device ball grids (for electrically coupling 140s—the electronic memory devices with 120A—the microprocessor) is denoted by 180. Package ball grids (for electrically coupling 120A—the microprocessor to 220—a package substrate) is denoted by 200.

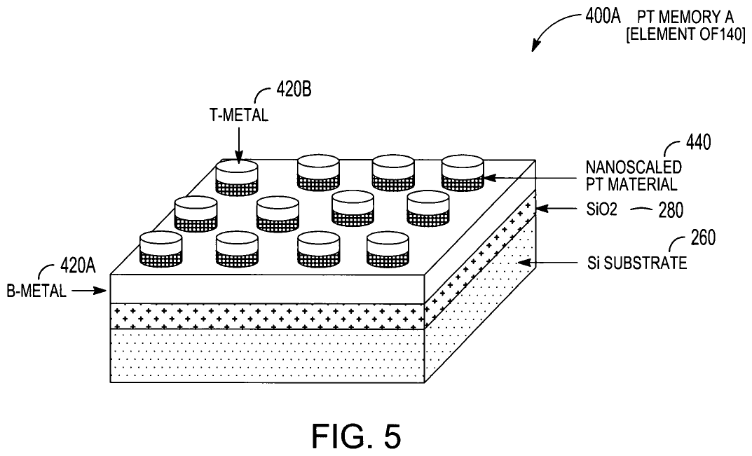

Furthermore, 120A—the microprocessor can also include a graphical processor. The building block (the element) of 140s—the electronic memory device are illustrated in FIGS. 5, 6, 7 and 8.

It should be noted that 140s—the electronic memory devices can integrate a combination of electronic memories as illustrated in FIGS. 5, 6, 7 and 8, depending on a particular performance need of 100A—the first system on chip.

FIG. 1B illustrates another embodiment of 100A—the first system on chip, utilizing a common platform—an interposer for electrically coupling 140s—the electronic memory devices onto a logic die-communicating via a physical layer connection (“PHY”) with 120A—the microprocessor on 220—the package substrate.

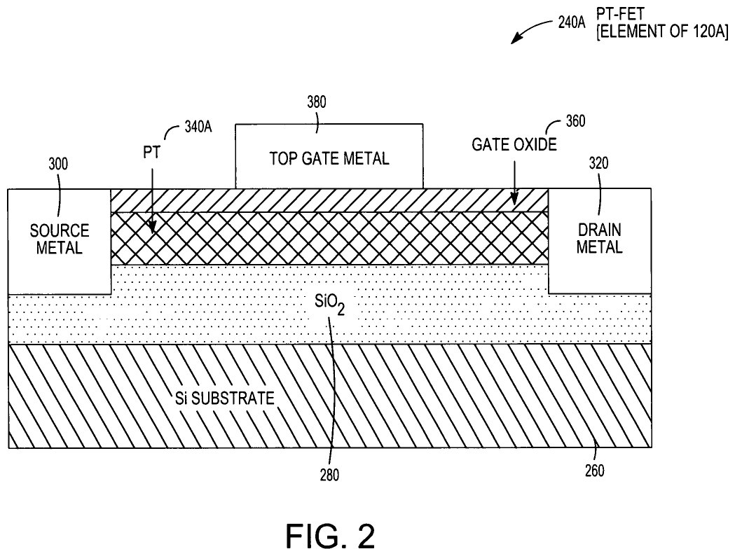

FIGS. 2-4 illustrate various embodiments of a building block (an element) of 120A—the microprocessor. The building block of 120A—the microprocessor can be a field effect transistor.

FIG. 2 illustrates 240A—a phase transition material based field effect transistor. In FIG. 2, a silicon substrate is denoted by 260, a silicon dioxide dielectric is denoted by 280, a source metal is denoted by 300, a drain metal is denoted by 320, a phase transition material is denoted by 340A, a gate oxide (e.g., hafnium oxide) is denoted by 360 and a top gate metal is denoted by 380.

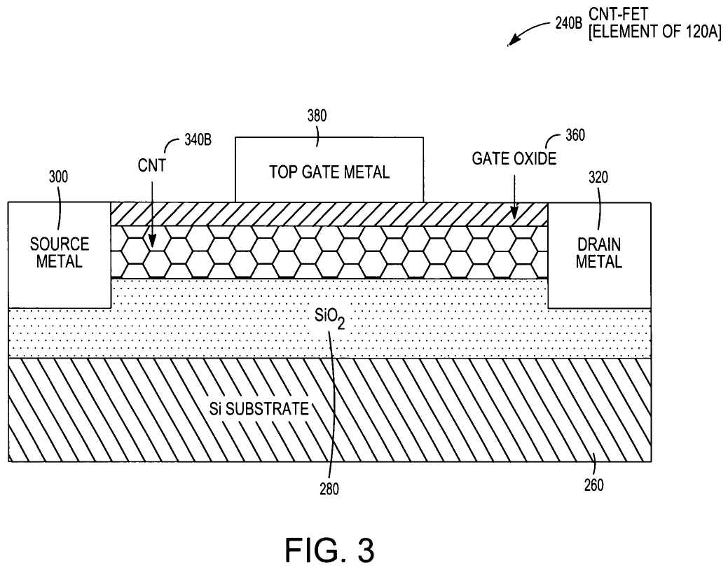

FIG. 3 illustrates 240B, carbon nanotube based field effect transistor. In FIG. 3, the silicon substrate is denoted by 260, the silicon dioxide dielectric is denoted by 280, the source metal is denoted by 300, the drain metal is denoted by 320, a carbon nanotube is denoted by 340B, the gate oxide is denoted by 360 and the top gate metal is denoted by 380. 340B—the carbon nanotube can be metallurgically coupled/connected/welded to the source metal 300 and the drain metal 320, utilizing a metal layer of 240—the carbon nanotube based field effect transistor.

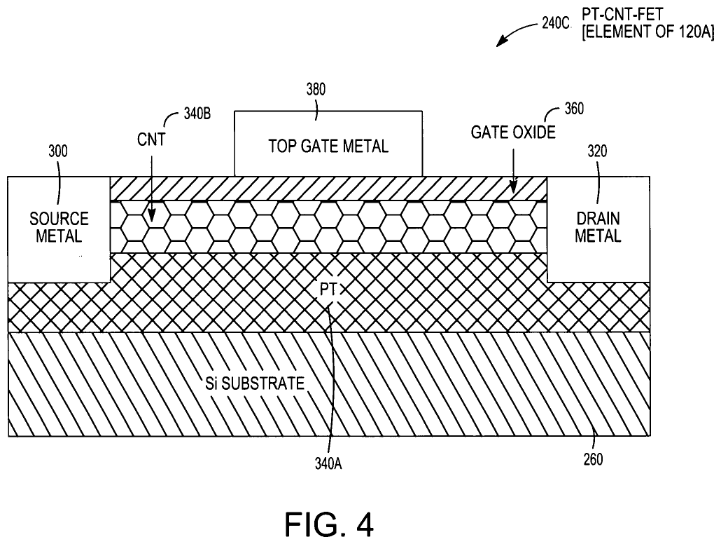

FIG. 4 illustrates 240C, a hybrid phase transition material-carbon nanotube based field effect transistor. In FIG. 4, the silicon substrate is denoted by 260, the silicon dioxide dielectric is denoted by 280, the source metal is denoted by 300, the drain metal is denoted by 320, a phase transition material is denoted by 340A, the carbon nanotube is denoted by 340B, the gate oxide is denoted by 360 and the top gate metal is denoted by 380. 340B—the carbon nanotube can be metallurgically coupled/connected/welded to the source metal 300 and the drain metal 320, utilizing a metal layer.

Many types of electronic memory devices (e.g., a dynamic random access memory (DRAM)/NAND flash) are used in present computing systems. Dynamic random access memory is an electronic volatile memory device that stores each bit of data in a separate capacitor. The capacitor can be either charged or discharged. These two states can represent the two values of a bit, conventionally called 0 and 1. The capacitor will slowly discharge and the data eventually fades, unless the capacitor charge is refreshed periodically. NAND flash memory device is an electronic non-volatile memory device that can be electrically erased and reprogrammed. Present invention of an electronic memory device based on a phase change material which can replace dynamic random access electronic memory device.

FIG. 5 illustrates an embodiment of a cross-sectional design of a cell of 400A—an electronic memory device based on a nanoscaled phase transition material. In FIG. 5, the silicon substrate is denoted by 260, the silicon dioxide dielectric is denoted by 280, a bottom metal is denoted by 420A, a nanoscaled phase transition material is denoted by 440 and a top metal is denoted by 420B.

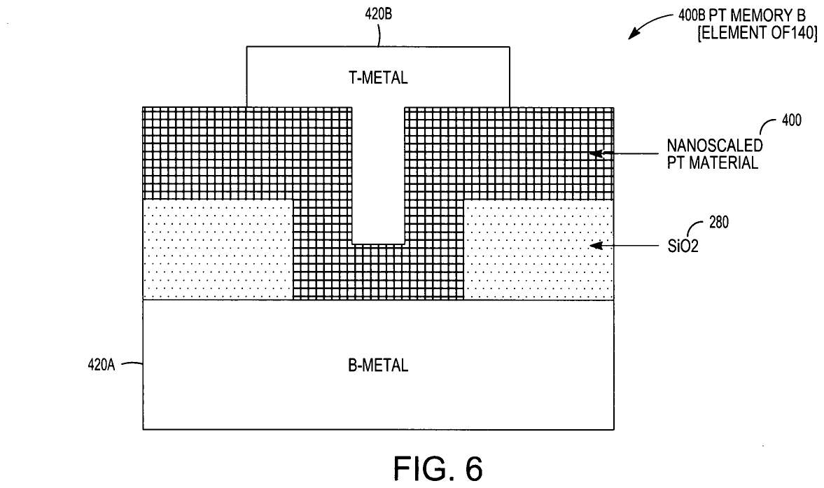

FIG. 6 illustrates another embodiment of a cross-sectional design of a cell of 440B—the electronic memory device based on a nanoscaled phase transition material. In FIG. 6, the bottom metal is denoted by 420A, the silicon dioxide is denoted by 280, the nanoscaled phase transition material is denoted by 440 and the top metal is denoted by 420B.

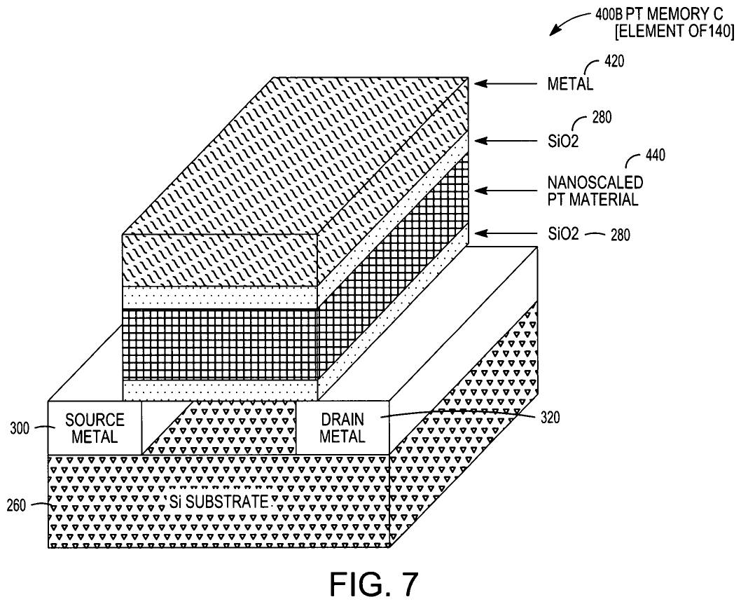

FIG. 7 illustrates another embodiment of a cross-sectional design of a cell of 400C—the electronic memory device based on nanoscaled phase transition material. In FIG. 7, the silicon substrate is denoted by 260, the source metal is denoted by 300, the drain metal is denoted by 320, the silicon dioxide is denoted by 280, the nanoscaled phase transition material is denoted by 440, another silicon dioxide (e.g., fabricated/constructed by atomic layer deposition (ALD)) is denoted by 280 and the metal is denoted by 420.

Furthermore, nanoscaled Hf_{0.5}Zr_{0.5}O₂ ferroelectric ultra thin-film (of about 15 nanometers to 30 nanometers in thickness) or nanoscaled amorphous boron nitride ultra thin-film (of about 2 nanometers to 10 nanometers in thickness) can replace both the nanoscaled phase transition material 440 and/or another silicon dioxide 280.

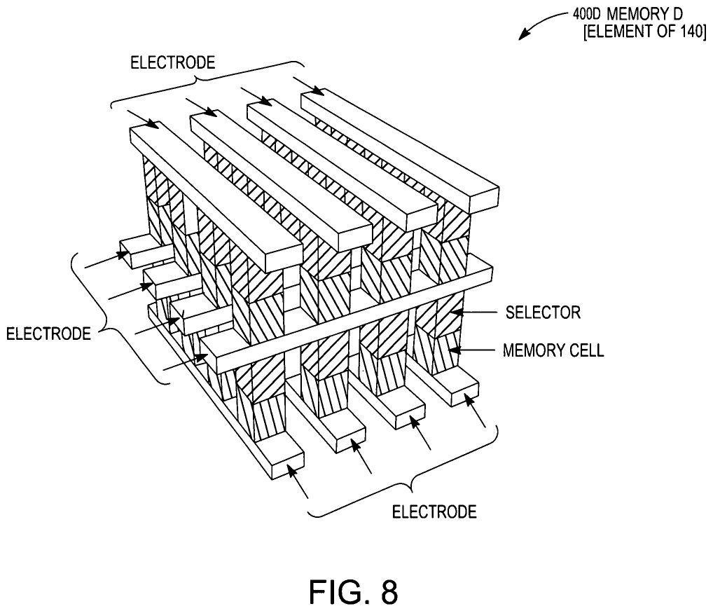

FIG. 8 illustrates another embodiment (stacked in a three-dimensional configuration) of a cross-sectional design of a cell of 400D—an electronic memory device based on a nanoscaled phase change (e.g., nanoscaled Ag₄In₃Sb₆₇Te₂₆ (AIST))/nanoscaled phase transition (e.g., nanoscaled vanadium dioxide) material. Here a cell of 400D—the electronic memory device can be individually selected by a selector device. About 15 nanometers to 30 nanometers thick Ag₄In₃Sb₆₇Te₂₆ based phase change material in the cell of 400D—the electronic memory device can replace dynamic random access memory electronic memory device. Ag₄In₃Sb₆₇Te₂₆ ultra thin-film (of about 15 nanometers to 30 nanometers thickness) can be excited by terahertz electrical pulses of few picoseconds in time duration and suitable (e.g., about 200 kV/cm) threshold electric field strength.

Furthermore, nanoscaled Ag₄In₃Sb₆₇Te₂₆ ultra thin-film (of about 15 nanometers to 30 nanometers thickness) can be also utilized as the selector device.

Additionally, nanoscaled Hf_{0.5}Zr_{0.5}O₂ ferroelectric ultra thin-film (of about 15 nanometers to 30 nanometers in thickness) or nanoscaled amorphous boron nitride ultra thin-film (of about 2 nanometers to 10 nanometers in thickness) can replace the nanoscaled phase transition material 440 and/or another silicon dioxide 280.

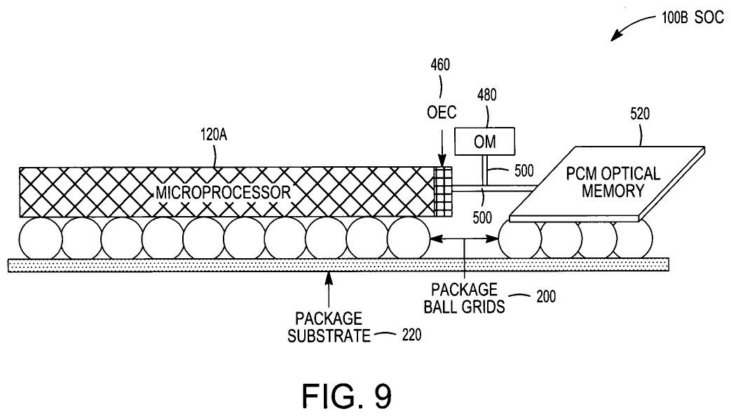

FIG. 9 illustrates an embodiment of 100B—a second system on chip. In FIG. 9, 120A—the microprocessor is optically coupled with 520—an optical memory device. In FIG. 9, the microprocessor is denoted by 120A, which is electrically coupled to the package substrate 220 with the package ball grids 200. 120A—the microprocessor is electro-optically coupled by 460—an optical signal to electrical signal converter (OEC) device.

460—the optical signal to electrical signal converter device can couple plasmons-polaritons through an interferometer. By applying a voltage on one arm of an interferometer, subsequently the refractive index and velocity of the plasmons in the one arm of the interferometer can be varied, which may change plasmons' amplitude of oscillation at an output exit. Then, plasmons are re-converted into light, which is coupled into 500—an optical waveguide.

Alternatively, 460—the optical signal to electrical signal converter device can include a metalized (e.g., tungsten) through-semiconductor via hole, a light source (e.g., a vertical cavity surface emitting laser), a photodetector and a microlens/microprism for optical waveguide-to-optical waveguide coupling. Furthermore, the light source may utilize one wavelength from 480—an optical module (OM)/device.

It should be noted that 140s—the electronic memory devices can integrate a combination of electronic memories as illustrated in FIGS. 5, 6, 7 and 8, depending on a particular performance need of 100B—the second system on chip.

The optical module/device is denoted by 480, which provides many wavelengths of controlled intensities. 480—the optical module/device includes a light source of one or more wavelengths or light sources of one or more wavelengths.

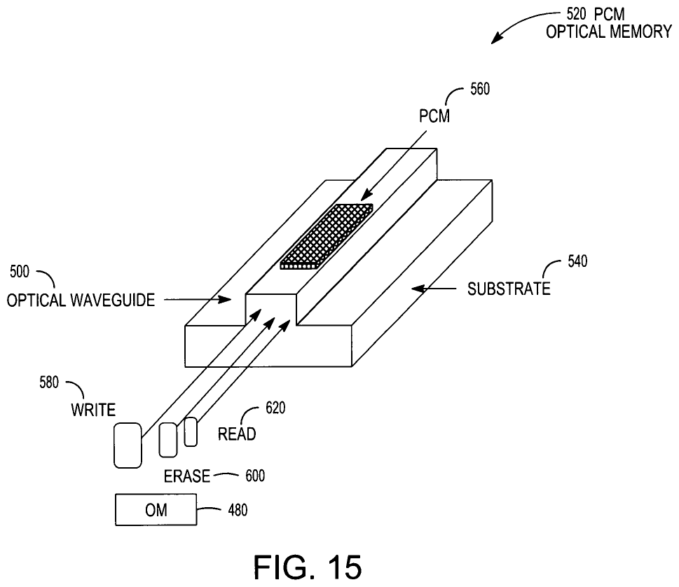

460—the optical signal to electrical signal converter device, 480—the optical module/device and 520—the optical memory device are optically coupled by 500—an optical waveguide. In FIG. 9, 120A-microprocessor can be optically coupled with 520—the optical memory device by 460—the optical signal to electrical signal converter device or 480—the optical module/device or 500—the optical waveguide or alternatively a combination of 460—the optical signal to electrical signal converter device, 480—the optical module/device and 500—the optical waveguide. Details of 520—the optical memory device are illustrated in FIG. 15.

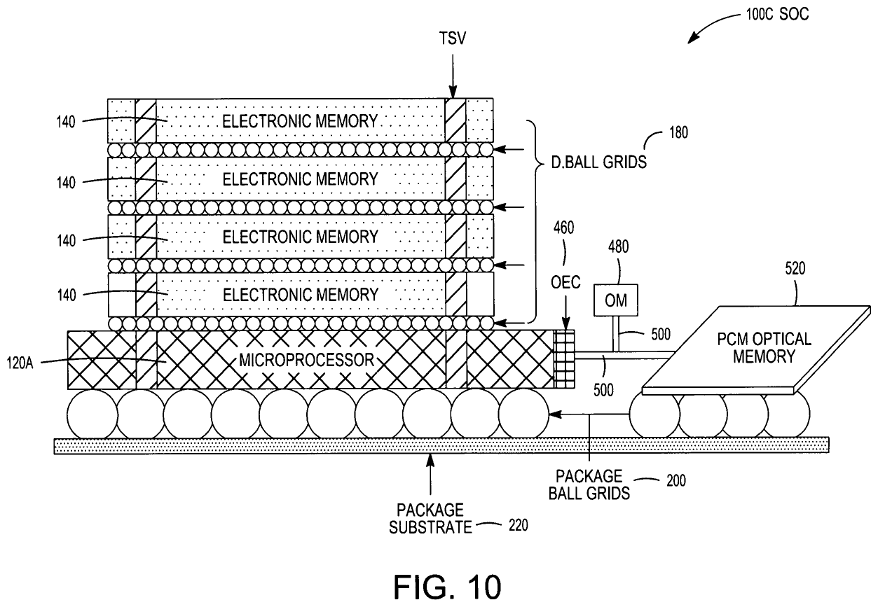

FIG. 10 illustrates an embodiment of 100C, a third system on chip. In FIG. 10, 120A—the microprocessor is optically coupled with 520—the phase change material (PCM) based optical memory device. FIG. 10 is similar to FIG. 9 with exception that 120A—the microprocessor is additionally electrically coupled with 140s—the electronic memory devices. 120A—the microprocessor is electrically coupled with 140s—the electronic memory devices through 160, the metalized through-semiconductor via hole. Device ball grids (for electrically connecting 140—the electronic memory devices with 120—the microprocessor) is denoted by 180. The package ball grids (for electrically coupling 120—the microprocessor to 220—the package substrate) is denoted by 200. In FIG. 10, 120A-microprocessor can be optically coupled with 520—the optical memory device by 460—the optical signal to electrical signal converter device or 480—the optical module/device or 500—the optical waveguide or alternatively a combination of 460—the optical signal to electrical signal converter device, 480—the optical module/device and 500—the optical waveguide.

It should be noted that 140s—the electronic memory devices can integrate a combination of electronic memories as illustrated in FIGS. 5, 6, 7 and 8, depending on a particular performance need of 100C—the third system on chip.

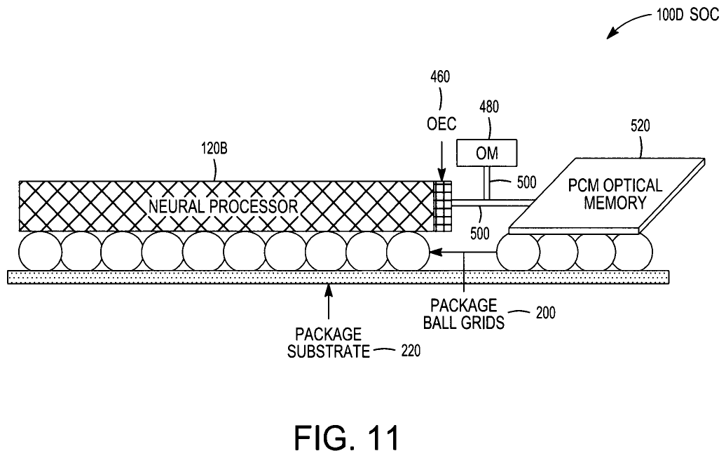

FIG. 11 illustrates an embodiment of 100D—a fourth system on chip. In FIG. 11, a neural processor is denoted by 120B, which is electrically coupled to the package substrate 220 with the package ball grids 200. 120B—the neural processor is electro-optically coupled by 460—the optical signal to electrical signal converter device. The optical module/device is denoted by 480, which provides many wavelengths of controlled intensities. 460—the optical signal to electrical signal converter, 480—the optical module/device and 520—the optical memory device are optically coupled by 500—the optical waveguide. In FIG. 11, 120B-neural processor can be optically coupled with 520—the optical memory device by 460—the optical signal to electrical signal converter device or 480—the optical module/device or 500—the optical waveguide or alternatively a combination of 460—the optical signal to electrical signal converter device, 480—the optical module/device and 500—the optical waveguide.

It should be noted that 140s—the electronic memory devices can integrate a combination of electronic memories as illustrated in FIGS. 5, 6, 7 and 8, depending on a particular performance need of 100D—the fourth system on chip.

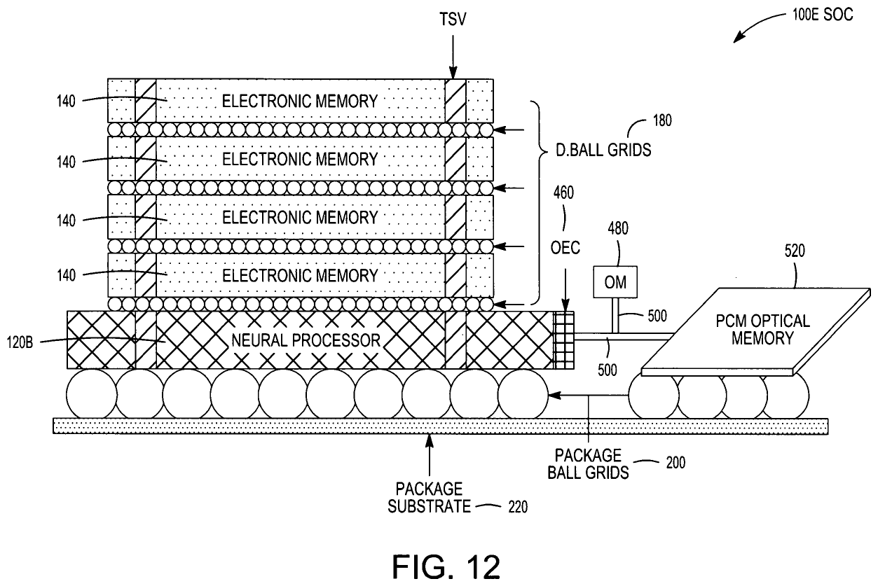

FIG. 12 illustrates an embodiment of 100E—a fifth system on chip. FIG. 12 is similar to FIG. 11 with exception that 120B—the neural processor is additionally electrically coupled with 140s—the electronic memory devices. In FIG. 12, 120B—the neural processor can be optically coupled with 520—the optical memory device by 460—the optical signal to electrical signal converter device or 480—the optical module/device or 500—the optical waveguide or alternatively a combination of 460—the optical signal to electrical signal converter device, 480—the optical module/device and 500—the optical waveguide.

It should be noted that 140s—the electronic memory devices can integrate a combination of electronic memories as illustrated in FIGS. 5, 6, 7 and 8, depending on a particular performance need of 100E—the fifth system on chip.

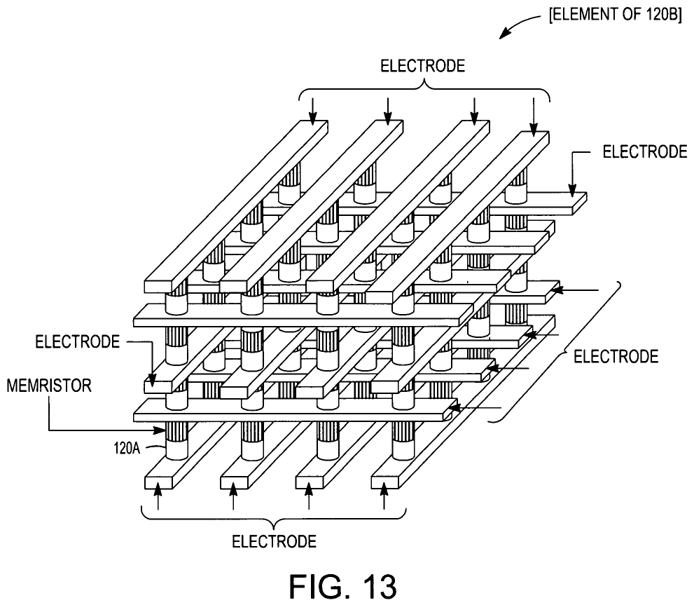

FIG. 13 illustrates an embodiment of a building block (an element) of 120B—the neural processor, which comprises microprocessors and memristors (e.g., a phase change/phase transition/ferroelectric/transition metal oxide (TMO)/silicon-rich oxide based material for the memristor) stacked in the three-dimensional (3-D) arrangement. Memristors can (a) save CPU processing bottleneck, (b) improve memory management, and (c) enable efficient in data processing due to interactions of memristors and transistors (of 120A—the microprocessor). In the transistor (of 120A—the microprocessor) once the flow of electrons is interrupted by, say, cutting the power, all information is lost. But a memristor can remember the amount of charge that was flowing through it and it has another fundamental difference compared with transistors—it can escape the rigid boundaries of microprocessor's digital binary codes. A memristor can also have multi-levels e.g., zero, one half, one quarter, one third and so on and that creates a very powerful memristive based smart neuromorphic computer, where it itself can adapt and learn/relearn. Alternatively, the building block (the element) of 120B—the neural processor can include memristors and just one 120A—the microprocessor. It should be noted that, any material of the memristor can be nanoscaled and 120A—the microprocessor can also include a graphical processor.

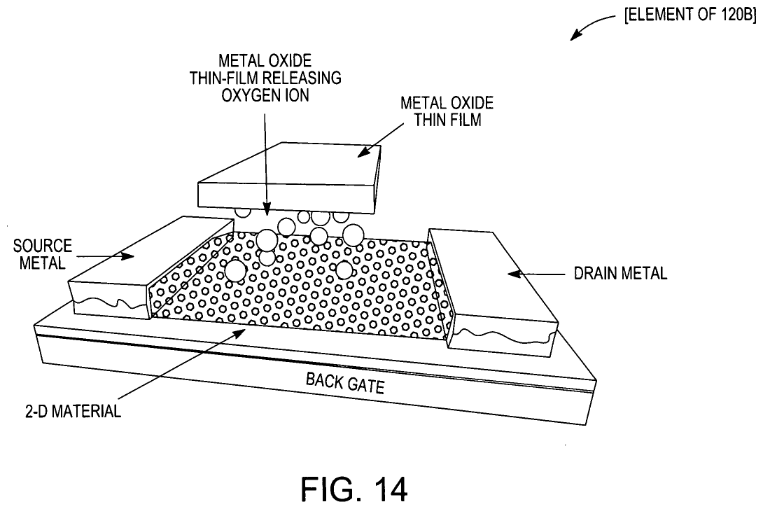

FIG. 14 illustrates another embodiment of a building block (an element) of 120B—the neural processor, which comprises a metal oxide layer releasing oxygen ions and field effect transistor, utilizing a two-dimensional material (e.g., graphene/indium selenide (InSe)), a source metal and a drain metal.

FIG. 15 illustrates an embodiment of 520—the optical memory device. In FIG. 15, 500—the optical waveguide is fabricated on 540—a substrate (e.g., silicon on insulator (SOI) substrate). 500—the optical waveguide has 560—a patch of a phase change material (PCM). 560—the patch of a phase change material is activated for writing, reading and erasing by various wavelengths of controlled optical intensities from 480—the optical module/device. Write wavelength (a first wavelength) of a controlled first optical intensity is denoted by 580, erase wavelength (a second wavelength) of a controlled second optical intensity is denoted by 600 and read wavelength (a third wavelength) of a controlled third optical intensity is denoted by 620. It should be noted that the second wavelength can be distinct/different from the first wavelength. The third wavelength can be distinct/different from the first wavelength and the second wavelength. The optical intensity of the second wavelength can be distinct/different from the optical intensity of the first wavelength. The optical intensity of the third wavelength can be distinct/different from the optical intensity of the first wavelength and the optical intensity of the second wavelength.

Furthermore, 560—the patch of the phase change material (e.g., germanium—antimony-tellurium (GST) or Ag₄In₃Sb₆₇Te₂₆) can be replaced by a phase transition material (e.g., vanadium dioxide). Additionally, it should be noted that the phase change material or the phase transition material can be nanoscaled.

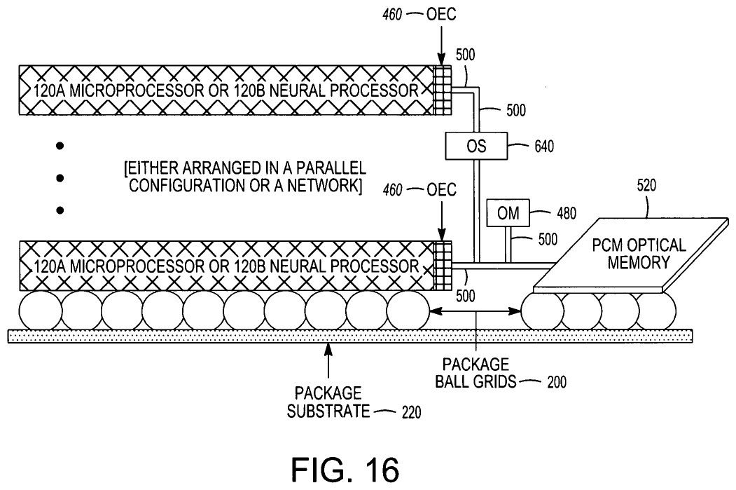

FIG. 16 illustrates an embodiment, wherein 120As—the microprocessors/120Bs—the neural processors (or even a network of 120As—the microprocessors/120Bs—the neural processors) are coupled with 640—an optical switch. It should be noted that 120A—the microprocessor can include a graphical processor.

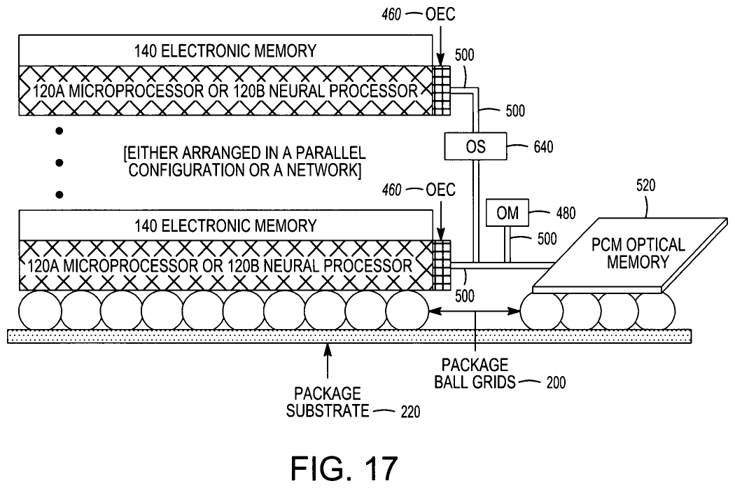

FIG. 17 illustrates an embodiment, wherein 120As—the microprocessors/120Bs—the neural processors (or even a network of 120As—the microprocessors/120Bs—the neural processors) are coupled with 640—the optical switch, wherein each 120A—the microprocessor/120B—the neural processor is further coupled with 140—the electronic memory of a phase change/phase transition material. It should be noted that 120A—the microprocessor can include a graphical processor.

Additionally, the phase change material/phase transition material can be nanoscaled (wherein, the nanoscaled is defined as less than 1000 nanometers in any dimension).

640—the optical switch from any example can be combined in any arrangement with two or more microprocessors/graphical processors/neural processors. 640—the optical switch can be activated by an electrical (e.g., a voltage/current) pulse or an optical pulse or a pulse of terahertz (THz) frequency (of a suitable field strength). It should be noted that activation of 640—the optical switch by an optical pulse or a pulse of terahertz frequency (of a suitable field strength) can switch 640—the optical switch in a few nanoseconds.

Details of an optical switch have been described/disclosed in U.S. non-provisional patent application Ser. Nos. 16/501,191 and 16/501,189 entitled “FAST OPTICAL SWITCH AND ITS APPLICATIONS IN OPTICAL COMMUNICATION”, filed on Mar. 5, 2019 and in its related U.S. non-provisional patent applications (with all benefit provisional patent applications) are incorporated in its entirety herein with this application.

In summary, a system including 120B—the neural processor, wherein 120B—the neural processor includes memristors, wherein the memristors are arranged in three-dimension (FIG. 13), wherein 120B—the neural processor is coupled with 520—the optical memory device by 460—the optical signal to electrical signal converter device and/or 500—the optical waveguide, wherein 460—the optical signal to electrical signal converter device is coupled with 480—the optical module, which provides/supplies three wavelengths—(i) a first wavelength for writing (580), (ii) a second wavelength for erasing (600) and (iii) a third wavelength for reading (620), wherein 520—the optical memory device is activated by (i) a first wavelength for writing (580), (ii) a second wavelength for erasing (600) and (iii) a third wavelength for reading (620), wherein 120B—the neural processor is further coupled with 140—the electronic memory device, which includes a phase change material of a nanoscaled dimension or a phase transition material of a nanoscaled dimension, wherein the nanoscaled dimension is less than 1000 nanometers in any dimension.

460—the optical signal to electrical signal converter device includes plasmons-polaritons, wherein the plasmons-polaritons are coupled with an interferometer.

Alternatively, 460—the optical signal to electrical signal converter device can include a metalized through-semiconductor via hole, a light source and a photodetector.

520—the optical memory device includes a phase change material or a phase transition material or alternatively, a phase change material of a nanoscaled dimension or a phase transition material of a nanoscaled dimension, wherein the nanoscaled dimension is less than 1000 nanometers in any dimension.

The above system includes 460—the electronic memory device of Ag₄In₃Sb₆₇Te₂₆ material of a nanoscaled dimension or Hf_{0.5}Zr_{0.5}O₂ material of a nanoscaled dimension or boron nitride material of a nanoscaled dimension, wherein the nanoscaled dimension is less than 1000 nanometers in any dimension.

It should be noted that the more than one 120B-neural processor can be coupled with 640—the optical switch and 120B—the neural processor is electrically coupled with 140—the electronic memory.

A system including 120A—the microprocessor (and/or a graphical processor) which is electrically coupled with 140—the electronic memory device, which includes a selector device, (FIG. 8) wherein 140—the electronic memory device includes Ag₄In₃Sb₆₇Te₂₆ material of a nanoscaled dimension or Hf_{0.5}Zr_{0.5}O₂ material of a nanoscaled dimension or boron nitride material of nanoscaled dimension, wherein the nanoscaled dimension is less than 1000 nanometers in any dimension, wherein Ag₄In₃Sb₆₇Te₂₆ material or Hf_{0.5}Zr_{0.5}O₂ material or boron nitride material is arranged in three-dimension, wherein the system is coupled with 520—the optical memory device by 460—the optical signal to electrical signal converter device and/or 500—the optical waveguide, wherein 520—the optical memory device is activated by (i) a first wavelength for writing (580), (ii) a second wavelength for erasing (600) and (iii) a third wavelength for reading (620). It should be noted that 120A—the microprocessor can include one or more carbon nanotube based field effect transistors or a phase transition material based field effect transistors or a phase change material based field effect transistors, wherein the carbon nanotube is metallurgically coupled with a source metal and a drain metal of the one field effect transistor.

460—the optical signal to electrical signal converter device includes plasmons-polaritons, wherein the plasmons-polaritons are coupled with an interferometer.

Alternatively, 460—the optical signal to electrical signal converter device includes a metalized through-semiconductor via hole, a light source and a photodetector.

It should be noted that more than one 120A—the microprocessor (and/or more than one graphical processor) can be coupled with 640—the optical switch and 120A—the microprocessor (and/or the graphical processor) is electrically coupled with 140—the electronic memory.

### PREFERRED EMBODIMENTS & SCOPE OF THE INVENTION

In the above disclosed specifications “/” has been used to indicate an “or”.

As used in this application and in the claims, the singular forms “a”, “an”, and “the” include also the plural forms, unless the context clearly dictates otherwise.

The term “includes” means “comprises”. The term “including” means “comprising”.

The term “couples” or “coupled” does not exclude the presence of an intermediate element(s) between the coupled items.

Any dimension in the above disclosed specifications is by way of an approximation only and not by way of any limitation.

Any example in the above disclosed specifications is by way of an example only and not by way of any limitation. Having described and illustrated the principles of the disclosed technology with reference to the illustrated embodiments, it will be recognized that the illustrated embodiments can be modified in any arrangement and detail with departing from such principles. The technologies from any example can be combined in any arrangement with the technologies described in any one or more of the other examples. Alternatives specifically addressed in this application are merely exemplary and do not constitute all possible examples. Claimed invention is disclosed as one of several possibilities or as useful separately or in various combinations. See Novozymes A/S v. DuPont Nutrition Biosciences APS, 723 F3d 1336, 1347.

The best mode requirement “requires an inventor(s) to disclose the best mode contemplated by him/her, as of the time he/she executes the application, of carrying out the invention.” “ . . . [T]he existence of a best mode is a purely subjective matter depending upon what the inventor(s) actually believed at the time the application was filed.” See Bayer AG v. Schein Pharmaceuticals, Inc. The best mode requirement still exists under the America Invents Act (AIA). At the time of the invention, the inventor(s) described preferred best mode embodiments of the present invention. The sole purpose of the best mode requirement is to restrain the inventor(s) from applying for a patent, while at the same time concealing from the public preferred embodiments of their inventions, which they have in fact conceived. The best mode inquiry focuses on the inventor(s)′ state of mind at the time he/she filed the patent application, raising a subjective factual question. The specificity of disclosure required to comply with the best mode requirement must be determined by the knowledge of facts within the possession of the inventor(s) at the time of filing the patent application. See Glaxo, Inc. v. Novopharm Ltd., 52 F.3d 1043, 1050 (Fed. Cir. 1995). The above disclosed specifications are the preferred best mode embodiments of the present invention. However, they are not intended to be limited only to the preferred best mode embodiments of the present invention.

Embodiment by definition is a manner in which an invention can be made or used or practiced or expressed. “A tangible form or representation of the invention” is an embodiment.

Numerous variations and/or modifications are possible within the scope of the present invention. Accordingly, the disclosed preferred best mode embodiments are to be construed as illustrative only. Those who are skilled in the art can make various variations and/or modifications without departing from the scope and spirit of this invention. It should be apparent that features of one embodiment can be combined with one or more features of another embodiment to form a plurality of embodiments. The inventor(s) of the present invention is not required to describe each and every conceivable and possible future embodiment in the preferred best mode embodiments of the present invention. See SRI Int'l v. Matsushita Elec. Corp. of America, 775F.2d 1107, 1121, 227 U.S.P.Q. (BNA) 577, 585 (Fed. Cir. 1985) (enbanc).

The scope and spirit of this invention shall be defined by the claims and the equivalents of the claims only. The exclusive use of all variations and/or modifications within the scope of the claims is reserved. The general presumption is that claim terms should be interpreted using their plain and ordinary meaning. See Oxford Immunotec Ltd. v. Qiagen, Inc. et al., Action No. 15-cv-13124-NMG. Unless a claim term is specifically defined in the preferred best mode embodiments, then a claim term has an ordinary meaning, as understood by a person with an ordinary skill in the art, at the time of the present invention. Plain claim language will not be narrowed, unless the inventor(s) of the present invention clearly and explicitly disclaims broader claim scope. See Sumitomo Dainippon Pharma Co. v. Emcure Pharm. Ltd., Case Nos. 17-1798; -1799; -1800 (Fed. Cir. Apr. 16, 2018) (Stoll, J). As noted long ago: “Specifications teach. Claims claim”. See Rexnord Corp. v. Laitram Corp., 274 F.3d 1336, 1344 (Fed. Cir. 2001). The rights of claims (and rights of the equivalents of the claims) under the Doctrine of Equivalents-meeting the “Triple Identity Test” (a) performing substantially the same function, (b) in substantially the same way and (c) yielding substantially the same result. See Crown Packaging Tech., Inc. v. Rexam Beverage Can Co., 559 F.3d 1308, 1312 (Fed. Cir. 2009)) of the present invention are not narrowed or limited by the selective imports of the specifications (of the preferred embodiments of the present invention) into the claims.

There are number of ways the written description requirement is satisfied. Applicant(s) does not need to describe every claim element exactly, because there is no such requirement (MPEP § 2163). Rather to satisfy the written description requirement, all that is required is “reasonable clarity” (MPEP § 2163.02). An adequate description may be made in anyway through express, implicit or even inherent disclosures in the application, including word, structures, figures, diagrams and/or equations (MPEP §§ 2163(I), 2163.02). The set of claims in this invention generally covers a set of sufficient number of embodiments to conform to written description and enablement doctrine. See Ariad Pharm., Inc. v. Eli Lilly & Co., 598 F.3d 1336, 1355 (Fed. Cir. 2010), Regents of the University of California v. Eli Lilly & Co., 119 F.3d 1559 (Fed. Cir. 1997) & Amgen Inc. v. Chugai Pharmaceutical Co. 927 F.2d 1200 (Fed. Cir. 1991).

Drawings under 37 C.F.R. § 1.83(a): In particular, as outlined in MPEP 608.02 Drawing [R-07.2015], the statutory requirement for showing the claimed invention only requires that the “applicant shall furnish a drawing where necessary for the understanding of the subject matter to be patented . . . ” (See 35 U.S.C. § 113, See also 37 CFR § 1.81(a), which states “[t]he applicant for a patent is required to furnish a drawing of the invention where necessary for the understanding of the subject matter sought to be patented . . . ”).

Furthermore, Amgen Inc. v. Chugai Pharmaceutical Co. exemplifies Federal Circuit's strict enablement requirements. Additionally, the set of claims in this invention is intended to inform the scope of this invention with “reasonable certainty”. See Interval Licensing, LLC v. AOL Inc. (Fed. Cir. Sep. 10, 2014). A key aspect of the enablement requirement is that it only requires that others will not have to perform “undue experimentation” to reproduce it. Enablement is not precluded by the necessity of some experimentation, “[t]he key word is ‘undue’, not experimentation.” Enablement is generally considered to be the most important factor for determining the scope of claim protection allowed. The scope of enablement must be commensurate with the scope of the claims. However, enablement does not require that an inventor disclose every possible embodiment of his invention. The scope of enablement must be commensurate with the scope of the claims. The scope of the claims must be less than or equal to the scope of enablement. See Promega v. Life Technologies Fed. Cir., December 2014, Magsil v. Hitachi Global Storage Fed. Cir. August 2012.

The term “means” was not used nor intended nor implied in the disclosed preferred best mode embodiments of the present invention. Thus, the inventor(s) has not limited the scope of the claims as mean plus function. The standard is “whether the words of the claim are understood by person of ordinary skill in the art to have a sufficiently definite meaning as the name for structure.” See Williamson v. Citrix Online, LLC, 792 F.3d 1339 (2015).

An apparatus claim with functional language is not an impermissible “hybrid” claim; instead, it is simply an apparatus claim including functional limitations. Additionally, “apparatus claims are not necessarily indefinite for using functional language . . . [f]unctional language may also be employed to limit the claims without using the means-plus-function format.” See National Presto Industries, Inc. v. The West Bend Co., 76 F. 3d 1185 (Fed. Cir. 1996), R.A.C.C. Indus. v. Stun-Tech, Inc., 178 F.3d 1309 (Fed. Cir. 1998) (unpublished), Microprocessor Enhancement Corp. v. Texas Instruments Inc. & Williamson v. Citrix Online, LLC, 792 F.3d 1339 (2015).

I claim:

1. A system comprising: more than one neural processor,
wherein the one neural processor comprises memristors,
wherein the one neural processor is coupled with an optical switch,
wherein the one neural processor is further coupled with an optical memory device by an optical signal to electrical signal converter (OEC) device,
wherein the optical signal to electrical signal converter (OEC) device is coupled with an optical device,
wherein the optical device comprises
(i) a first wavelength for writing,
(ii) a second wavelength for erasing,
(iii) a third wavelength for reading,
wherein the optical memory device is activated by
(i) a first wavelength for writing,
(ii) a second wavelength for erasing,
(iii) a third wavelength for reading,
wherein the one neural processor is further coupled with an electronic memory device,
wherein the electronic memory device comprises a phase change material of a nanoscaled dimension, or a phase transition material of a nanoscaled dimension,
wherein the nanoscaled dimension is less than 1000 nanometers in any dimension.

2. The system according to claim 1, wherein the optical signal to electrical signal converter (OEC) device comprises plasmons-polaritons.

3. The system according to claim 2, wherein the plasmons-polaritons are coupled with an interferometer.

4. The system according to claim 1, wherein the optical signal to electrical signal converter (OEC) device comprises a metalized via hole, a light source and a photodetector.

5. The system according to claim 1, wherein the optical memory device comprises a phase change material, or a phase transition material.

6. The system according to claim 1, wherein the optical memory device comprises a phase change material of a nanoscaled dimension, or a phase transition material of a nanoscaled dimension, wherein the nanoscaled dimension is less than 1000 nanometers in any dimension.

7. The system according to claim 1, wherein the electronic memory device comprising the phase change material of a nanoscaled dimension, or the phase transition material of a nanoscaled dimension is replaced by (i) Hf_{0.5}Zr_{0.5}O₂ material of nanoscaled dimension, or (ii) boron nitride material of nanoscaled dimension, wherein the nanoscaled dimension is less than 1000 nanometers in any dimension.

8. A system comprising:
(a) an electronic memory device; and
(b) more than one neural processor,
wherein the one neural processor comprises memristors,
wherein the one neural processor is coupled with an optical switch,
wherein the one neural processor is further coupled with the electronic memory device,
wherein the one neural processor is further coupled with an optical memory device by an optical signal to electrical signal converter (OEC) device, and/or an optical waveguide,
wherein the optical memory device is activated by
(i) a first wavelength for writing,
(ii) a second wavelength for erasing,
(iii) a third wavelength for reading.

9. The system according to claim 8, wherein the optical signal to electrical signal converter (OEC) device comprises plasmons-polaritons.

10. The system according to claim 9, wherein the plasmons-polaritons are coupled with an interferometer.

11. The system according to claim 8, wherein the optical signal to electrical signal converter (OEC) device comprises a metalized via hole, a light source and a photodetector.

12. The system according to claim 8, wherein the optical memory device comprises a phase change material, or a phase transition material.

13. The system according to claim 8, wherein the optical memory device comprises a phase change material of a nanoscaled dimension, or a phase transition material of a nanoscaled dimension, wherein the nanoscaled dimension is less than 1000 nanometers in any dimension.

14. The system according to claim 8, wherein the electronic memory device comprises a phase change material of a nanoscaled dimension, or a phase transition material of a nanoscaled dimension, wherein the nanoscaled dimension is less than 1000 nanometers in any dimension.

15. The system according to claim 8, wherein the electronic memory device comprises Ag₄In₃Sb₆₇Te₂₆ (AIST) material of a nanoscaled dimension, or Hf_{0.5}Zr_{0.5}O₂ material of nanoscaled dimension, or boron nitride material of nanoscaled dimension, wherein the nanoscaled dimension is less than 1000 nanometers in any dimension.

16. A system comprising:
more than one microprocessor, and/or more than one graphical processor,
wherein the one microprocessor, and/or the one graphical processor is coupled with an optical switch,
wherein the microprocessor, and/or the graphical processor is further electrically coupled with an electronic memory device,
wherein the electronic memory device comprises a selector device,
wherein the electronic memory device comprises Ag₄In₃Sb₆₇Te₂₆ (AIST) material of a nanoscaled dimension, or Hf_{0.5}Zr_{0.5}O₂ material of a nanoscaled dimension, or boron nitride material of nanoscaled dimension, wherein the nanoscaled dimension is less than 1000 nanometers in any dimension, wherein Ag₄In₃Sb₆₇Te₂₆ (AIST) material, or Hf_{0.5}Zr_{0.5}O₂ material, or boron nitride material is arranged in three-dimension (3-D),
wherein the system is coupled with an optical memory device by an optical signal to electrical signal converter (OEC) device, and/or an optical waveguide,
wherein the optical memory device is activated by
(i) a first wavelength for writing,
(ii) a second wavelength for erasing,
(iii) a third wavelength for reading.

17. The system according to claim 16, wherein the optical signal to electrical signal converter (OEC) device comprises plasmons-polaritons.

18. The system according to claim 17, wherein the plasmons-polaritons are coupled with an interferometer.

19. The system according to claim 16, wherein the optical signal to electrical signal converter (OEC) device comprises a metalized via hole, a light source and a photodetector.

20. The system according to claim 16, wherein the microprocessor comprises one or more carbon nanotube based field effect transistors, or a phase transition material based field effect transistors, or a phase change material based field effect transistors, wherein the one carbon nanotube is metallurgically coupled with a source metal and a drain metal of the one carbon nanotube based field effect transistor.

21. A system comprising:
(a) an electronic memory device; and
(b) more than one neural processor,
wherein the one neural processor comprises memristors,
wherein the one neural processor is coupled with an optical switch,
wherein the one neural processor is further coupled with the electronic memory device,
wherein the one neural processor is further coupled with an optical memory device by an optical signal to electrical signal converter (OEC) device, and/or an optical waveguide,
wherein the optical signal to electrical signal converter (OEC) device comprises a metalized via hole, a light source and a photodetector,
wherein the optical memory device is activated by
(i) a first wavelength for writing,
(ii) a second wavelength for erasing,
(iii) a third wavelength for reading.

22. The system according to claim 21, wherein the optical signal to electrical signal converter (OEC) device comprising (i) the metalized via hole, the light source and the photodetector are replaced by (ii) plasmons-polaritons.

23. The system according to claim 22, wherein the plasmons-polaritons are coupled with an interferometer.

24. A system comprising:
more than one microprocessor, and/or more than one graphical processor,
wherein the one microprocessor, and/or the one graphical processor is coupled with an optical switch,
wherein the microprocessor, and/or the graphical processor is further electrically coupled with an electronic memory device,
wherein the electronic memory device comprises a selector device,
wherein the electronic memory device comprises Ag₄In₃Sb₆₇Te₂₆ (AIST) material of a nanoscaled dimension, or Hf_{0.5}Zr_{0.5}O₂ material of a nanoscaled dimension, or boron nitride material of nanoscaled dimension, wherein the nanoscaled dimension is less than 1000 nanometers in any dimension, wherein Ag₄In₃Sb₆₇Te₂₆ (AIST) material, or Hf_{0.5}Zr_{0.5}O₂ material, or boron nitride material is arranged in three-dimension (3-D),
wherein the system is coupled with an optical memory device by an optical signal to electrical signal converter (OEC) device, and/or an optical waveguide,
wherein the optical signal to electrical signal converter (OEC) device comprises a metalized via hole, a light source and a photodetector,
wherein the optical memory device is activated by
(i) a first wavelength for writing,
(ii) a second wavelength for erasing,
(iii) a third wavelength for reading.

25. The system according to claim 24, wherein the optical signal to electrical signal converter (OEC) device comprising (i) the metalized via hole, the light source and the photodetector are replaced by (ii) plasmons-polaritons.

26. The system according to claim 25, wherein the plasmons-polaritons are coupled with an interferometer.
